(19) United States
(12) Patent Application Publication
(10) Pub. No.: US 2023/0050295 A1
(43) Pub. Date: Feb. 16, 2023

(54) MICROWAVE OVEN COMPRISING ELECTROMAGNETIC SHIELDING DEVICE

(71) Applicant: SAMSUNG ELECTRONICS CO., LTD., Suwon-si (KE)

(72) Inventors: Jinjoo KIM, Suwon-si (KR); Kwangmo YANG, Suwon-si (KR); Siho JANG, Suwon-si (KR)

(73) Assignee: SAMSUNG ELECTRONICS CO., LTD., Suwon-si (KR)

(21) Appl. No.: 17/975,097

(22) Filed: Oct. 27, 2022

Related U.S. Application Data
(63) Continuation of application No. PCT/KR2021/004587, filed on Apr. 12, 2021.

(30) Foreign Application Priority Data
Apr. 27, 2020 (KR) 10-2020-0050977

(51) Int. Cl. H05B 6/76

(52) U.S. Cl. CPC H05B 6/76

(57) ABSTRACT

According to various embodiments of the disclosure, a microwave oven may include: a main body including a cooking chamber and a front panel; a door to the main body including a door frame corresponding to the front panel; and a shielding device connected to the door to shield electromagnetic waves leaking from the cooking chamber. The shielding device may include: a choke unit extending from the door frame and including a plurality of portions constructed by being bent at least once; and a choke covering the choke unit. The choke cover may include a first portion constructed of a first material coupled to a portion of the choke unit; and a second portion connected integrally with the first portion and constructed of a second material different from the first material.

### CROSS-REFERENCE TO RELATED APPLICATION

This application is a by-pass continuation of International Application No. PCT/KR2021/004587, filed on Apr. 12, 2021, in the Korean Intellectual Property Receiving Office, which is based on and claims priority to Korean Application No. 10-2020-0050977, filed on Apr. 27, 2020, in the Korean Intellectual Property Office, the entire disclosures of which are incorporated herein by reference.

### TECHNICAL FIELD

Various embodiments of the disclosure relate to a device for shielding electromagnetic waves leaking from a microwave oven.

### BACKGROUND

In general, a cooking device using microwaves, e.g., a microwave oven, uses high-frequency waves (approximately 2.45 GHz) generated through magnetrons as a heating source. When this high-frequency wave is irradiated to a cooking chamber which is a space for accommodating food, molecules of the food vibrate to be heated up. In this case, the high-frequency wave may leak through a crevice between the cooking chamber and a door for opening/closing the cooking chamber. Various methods may be attempted to shield electromagnetic waves generated by such a door opening/closing structure.

Referring to FIG. 1, a cooking appliance, for example, a microwave oven 10, may include a main body 11 having a cooking chamber 111, and a door 12 for opening/closing the main body 11. The door 12 may be opened/closed in the main body 11 by means of a latch 121. In a state of being closed in the main body 11, the microwave oven 10 may have a shielding device for preventing leakage of electromagnetic waves from the cooking chamber 111.

For example, in the door 12 of the microwave oven 10, the electromagnetic waves may be shielded through resonance of an LC circuit of a choke unit. The shielding of the electromagnetic waves may be achieved according to a shape of the choke unit, e.g., a width or length of the choke unit. In particular, the length of the choke unit mainly affects the leakage of the electromagnetic waves. Accordingly, the leakage of the electromagnetic waves may be reduced by changing the shape of the choke itself or by optimizing the length thereof

Referring to FIG. 2 to FIG. 4, the microwave oven 10 is a cooking appliance capable of conveniently cooking food by using electromagnetic waves (2.4 to 2.5 GHz). A main body 21 (e.g., the main body 11 of FIG. 1) may include a front panel 210, and the door may include a door frame 220 and a choke unit 240 which attenuates electromagnetic waves of a corresponding frequency. The choke unit 240 may include a choke cover 230 for protecting from food. The choke cover 230 is hook-coupled to the choke unit to reinforce rigidity of the choke and to protect the choke from foreign substances when cooking food or cleaning the door. For example, a material of the choke cover 230 is an injection molded product constructed of a polypropylene material and has a permittivity of about 1.5.

When the door 12 of the microwave oven is closed, a crevice exists between the main body 21 and the door 12, and the leakage of electromagnetic waves occurs through this crevice. An upper limit thereof may be set as a standard to manage the leakage of the electromagnetic waves. The electromagnetic waves of the microwave oven 10 may be shielded through resonance of an LC circuit of the choke unit 240 of the door 12.

$${f}_{r} = \frac{1}{2 π \sqrt{L C}} \qquad Eqn ( 1 )$$

Referring to Equation 1 above, a size of the choke unit 240 is related to a length L of the choke. It is optimized so that electromagnetic waves are totally reflected inside the choke unit 240 by using a λ/4 value, i.e., a length which makes impedance infinity in a direction in which electromagnetic waves travel.

However, an energy source of the conventional microwave oven has L and C sizes optimized for 2.45 GHz and generates resonance at a corresponding frequency to shield electromagnetic waves. In particular, since a length of L is related to a wavelength, it may be difficult to reduce a size of the choke.

According to various embodiments of the disclosure, a shielding device capable of effectively shielding electromagnetic waves by adding a material having a shielding function of a choke unit is provided.

According to various embodiments of the disclosure, a shielding device that is advantageous for making a microwave oven small in size since it is possible to reduce a size of a front panel while adding a material having a shielding function of a choke unit is provided.

According to various embodiments of the disclosure, a shielding device that is advantageous for increasing a volume of a cooking chamber of a microwave oven is provided a size of a front panel may be reduced while adding a material having a shielding function of a choke unit.

According to various embodiments of the disclosure, a shielding device that is capable of saving logistics cost is provided because a size of a front panel may be reduced while adding a material having a shielding function of a choke unit, and thus reducing the packaging size to a small-sized front panel of a microwave oven.

### SUMMARY

According to various embodiments of the disclosure, a microwave oven may include: a main body including a cooking chamber and a front panel; a door to the main body including a door frame corresponding to the front panel; a shielding device connected to the door to shield electromagnetic waves leaking from the cooking chamber. The shielding device may include: a choke unit extending from the door frame and including a plurality of portions constructed by being bent at least once; and a choke cover covering the choke unit. The choke cover may include: a first portion constructed of a first material coupled to a portion of the choke unit; and a second portion connected integrally with the first portion and constructed of a second material different from the first material.

According to various embodiments of the disclosure, a microwave oven may include: a main body including a cooking chamber and a front panel; a door to the main body including a door frame corresponding to the front panel; and a shielding device connected to the door to shield electromagnetic waves leaking from the cooking chamber. The shielding device may include: a choke unit extending from the door frame and including a plurality of portions constructed by being bent at least once; a choke covering the choke unit and coupled to a portion of the choke unit; and an electromagnetic shielding layer between the choke unit and the choke cover.

According to various embodiments of the disclosure, a reduction in a width of a front panel due to a decrease in a size of a choke unit results in a small-sized microwave oven, an increase in a volume of a cooking chamber, and saving logistics cost caused by a decrease in a packaging size of the microwave oven.

### BRIEF DESCRIPTION OF DRAWINGS

The above and/or other aspects will be more apparent by describing certain exemplary embodiments with reference to the accompanying drawings, in which:

FIG. 1 is a perspective view illustrating a microwave oven according to various embodiments;

FIG. 2 is a perspective view illustrating a front panel of a main body according to various embodiments;

FIG. 3 is a perspective view illustrating a state in which a choke cover is coupled to a door frame according to various embodiments;

FIG. 4 is a perspective view illustrating a state in which a choke unit and a choke cover are coupled according to various embodiments;

FIG. 5A illustrates a shielding device of a door, in which (a) is a side view illustrating the conventional choke structure, and (b) is a side view illustrating a choke structure according to an embodiment of the disclosure;

FIG. 5B is an enlarged side view illustrating the choke structure of FIG. 5A;

FIG. 6 is a graph illustrating electromagnetic shielding results depending on a width of a front panel, according to the conventional shielding structure and the shielding structure of the disclosure illustrated in FIG. 5B;

FIG. 7A illustrates a shielding device of a door, in which (a) is a side view illustrating the conventional choke structure, and (b) is a side view illustrating a choke structure according to an embodiment of the disclosure;

FIG. 7B is an enlarged side view illustrating the choke structure of FIG. 7A;

FIG. 8 is a side view illustrating a choke unit according to an embodiment of the disclosure;

FIG. 9 is a perspective view illustrating a state of arranging an electromagnetic shielding layer disposed to a choke unit according to an embodiment of the disclosure; and

FIG. 10 is a graph illustrating electromagnetic shielding results depending on a width of a front panel, according to the conventional shielding structure and the shielding structure of the disclosure illustrated in FIG. 7B.

### DETAILED DESCRIPTION

Hereinafter, various embodiments of the disclosure are described with reference to the accompanying drawings. However, it should be appreciated that this is not intended to limit the technological features set forth herein to particular embodiments and include various changes, equivalents, or replacements for an embodiment of the disclosure. With regard to the description of the drawings, similar reference numerals may be used to refer to similar or related elements.

In the following description, like drawing reference numerals are used for like elements, even in different drawings. The matters defined in the description, such as detailed construction and elements, are provided to assist in a comprehensive understanding of the exemplary embodiments. However, it is apparent that the exemplary embodiments can be practiced without those specifically defined matters. Also, well-known functions or constructions may not be described in detail because they would obscure the description with unnecessary detail.

It will be understood that the terms “include,” “including,” “comprises” and/or “comprising” used herein specify the presence of stated features or components, but do not preclude the presence or addition of one or more other features or components. In addition, the terms such as “circuit”, “unit,” “-er (-or),” and “module” described in the specification refer to an element for performing at least one function or operation, and may be implemented in hardware, software, or the combination of hardware and software.

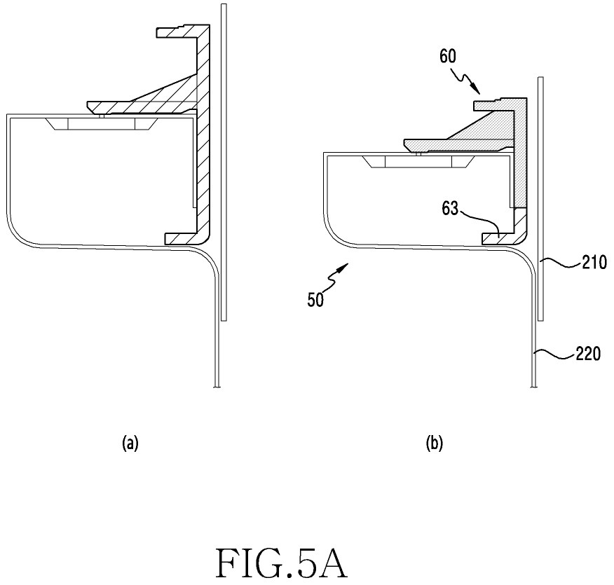

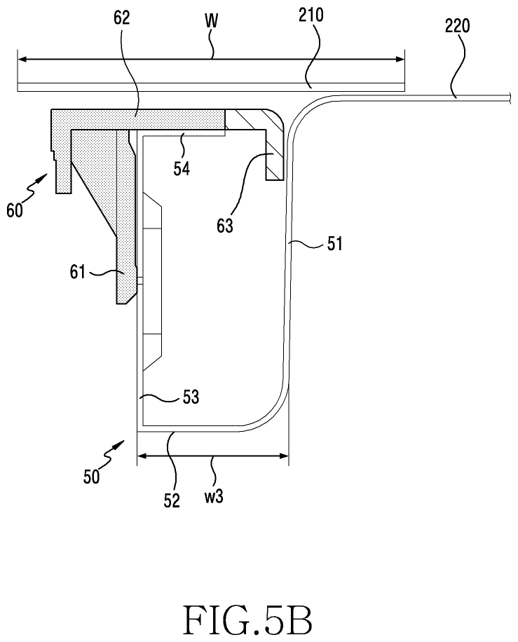

According to an embodiment, a microwave oven may include an electromagnetic shielding device. For example, as shown in FIGS. 5B and 5B, the electromagnetic shielding device may be disposed to a choke unit 50 and a choke cover 60.

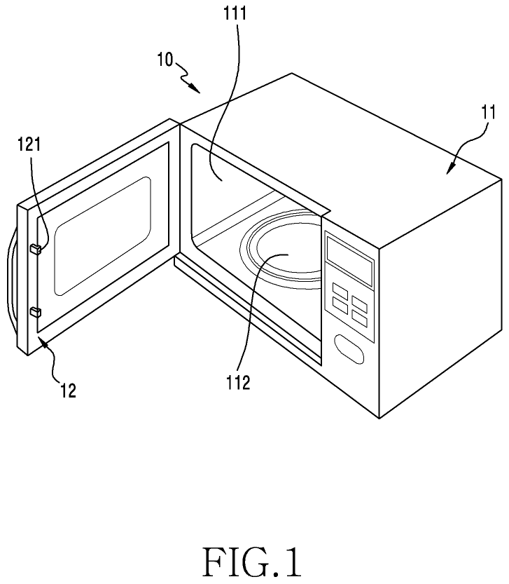

The microwave oven according to an embodiment (e.g., the microwave oven 10 of FIG. 1) may have a shielding device disposed to a door (e.g., the door 12 of FIG. 1) to block leakage of electromagnetic waves. The shielding device according to an embodiment may include the choke unit 50 extending from the door frame 220 and the choke cover 60 having a shielding function.

According to an embodiment, the choke unit 50 includes a first side portion 51, an inner portion 52, a second side portion 53, and an outer portion 54. The plurality of outer portions 54 may be arranged. According to an embodiment, the plurality of arranged outer portions 54 may be arranged to face the front panel 210.

According to an embodiment, the choke cover 60 may be constructed of a material capable of maintaining certain rigidity, and may be disposed to surround at least one portion of the choke unit 50 and thus perform a cover function of the choke unit 50 against foreign substances. The at least one portion thereof may be constructed of an electromagnetic shielding material to perform an electromagnetic shielding function. In particular, an electromagnetic shielding effect may be improved by increasing a bandwidth of a resonance frequency.

According to an embodiment, in the choke cover 60, a portion facing the front panel 210 may be constructed of a material having a high relative permittivity and having a shielding capability, and the remaining portions may be constructed of a material having a permittivity closest to that of air so that electromagnetic waves smoothly travel within the choke unit 50, by considering a characteristic in which leaked electromagnetic waves are totally reflected within the choke unit 50.

According to an embodiment, the choke cover 60 may surround at least one portion of the choke unit 50, and may be coupled to the at least one portion of the choke unit 50. According to an embodiment, the choke cover 60 may be constructed by combining two heterogeneous materials. According to an embodiment, the choke cover 60 may include first portions 61 and 62 constructed of a first material. For example, the first material is an electromagnetic shielding material having a high permittivity (e.g., a relative permittivity: 37-40), and may include any one of Carbon Nano Tube (CNT) and Chlorinated Polyethylene (CPE).

According to an embodiment, the choke cover 60 may include a second portion 63 constructed of a second material. For example, the second material may include a polypropylene material.

According to an embodiment, the first and second portions 61 and 62 are rectangular in shape, and may include the portion 51 coupled to the second side portion 53 and the portion 52 disposed close to the outer portion 54 and disposed to face the front panel 210.

According to an embodiment, the second portion 63 may extend from an end of the first portion 62, and may extend in a direction parallel to the front panel 210. According to an embodiment, an end of the second portion 63 may be bent to extend toward the inner portion 52. For example, the first and second portions 61, 62 and 63 may be manufactured by using a double injection technique.

According to an embodiment, when a microwave oven (e.g., the microwave oven 10 of FIG. 1) operates, electromagnetic waves generated inside a cooking chamber (e.g., the cooking chamber 111 of FIG. 1) may be totally reflected and trapped mostly inside the choke unit 50. Electromagnetic waves leaked between the front panel 210 and the choke unit 50 are increased in bandwidth at a resonance frequency due to the first portions 61 and 62, thereby preventing the electromagnetic waves from leaking to the outside of the door 12.

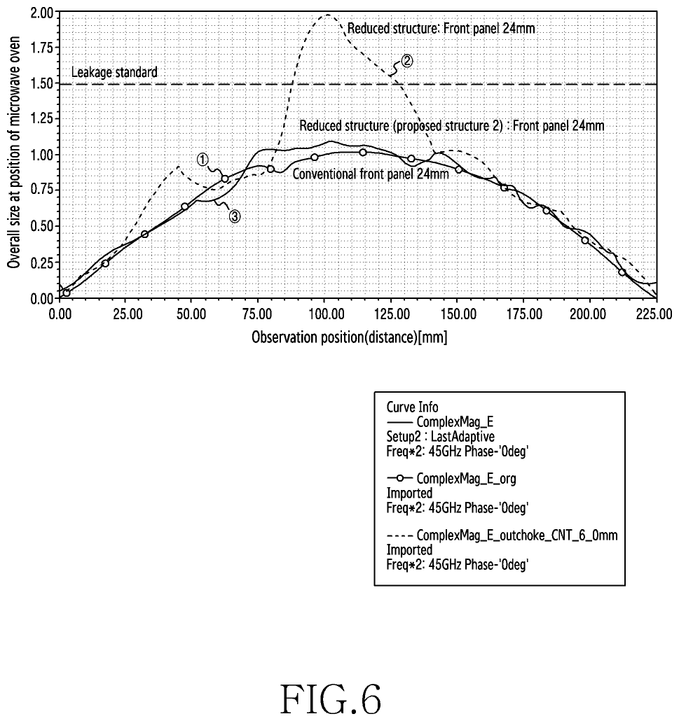

Referring to FIG. 6, a reference number \textcircled{1} represents a case of a conventional electromagnetic shielding structure (the front panel 210 has a width of 34 mm), a reference number \textcircled{2} represents a case of a conventional electromagnetic shielding structure in which the front panel 210 has a width of 24 mm. A reference numeral \textcircled{3} represents a case of an electromagnetic shielding structure according to an embodiment of the disclosure in which the front panel 210 has a width of 24 mm.

The conventional electromagnetic shielding structure (e.g., shown in (a) of FIG. 5A) indicated by the reference numeral \textcircled{1} of FIG. 6 uses the choke cover 60 constructed of a polypropylene material having a relative permittivity of 1.5. The choke cover has a purpose of protecting the choke unit 50 and does not have an electromagnetic shielding function. The conventional electromagnetic shielding structure may not deviate from a standard of electromagnetic wave leakage.

The conventional electromagnetic shielding structure of \textcircled{2} of FIG. 6 uses the choke cover 60 constructed of a polypropylene material having a relative permittivity of 1.5. The choke cover has a purpose of protecting the choke unit 50 and does not have an electromagnetic shielding function. The conventional electromagnetic shielding structure may deviate from the standard of electromagnetic wave leakage in some sections.

The electromagnetic shielding structure of \textcircled{3} of FIG. 6 according to an embodiment of the disclosure may shield electromagnetic waves without deviation from the standard of electromagnetic wave leakage.

The electromagnetic shielding structure (e.g., shown in FIG. 5B) according to an embodiment may perform an electromagnetic shielding function without deviation from the standard of electromagnetic wave leakage even if the width of the front panel 210 is reduced by 10 mm compared to the conventional structure. In addition, in the electromagnetic shielding structure according to an embodiment, it is possible to decrease a size of the choke unit and decrease a size of the front panel (e.g., 10 mm).

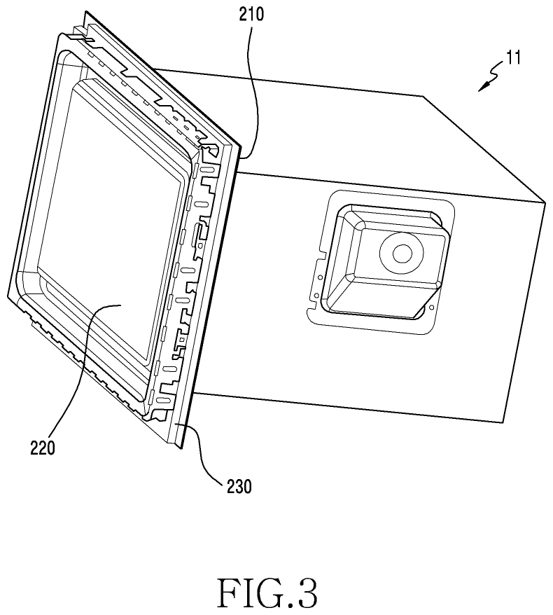

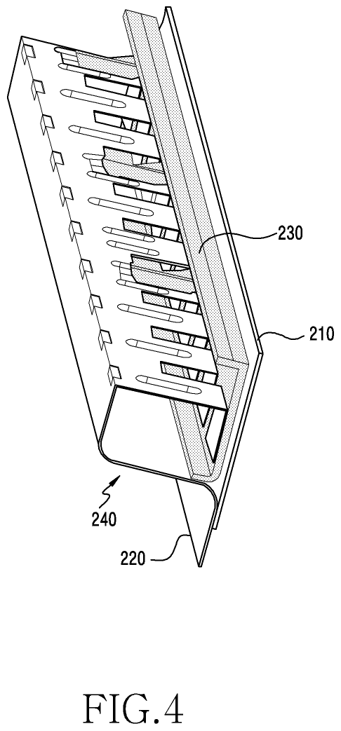

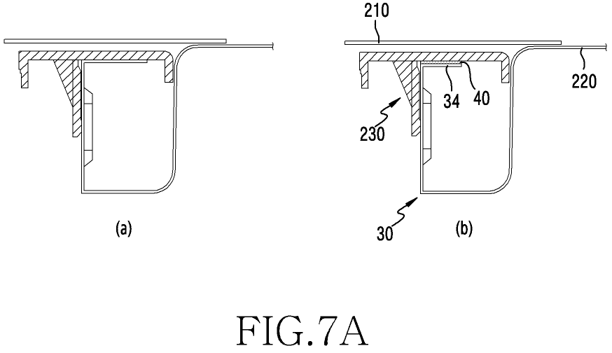

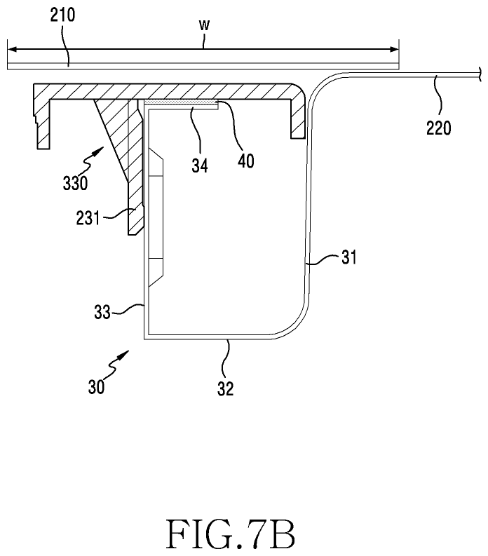

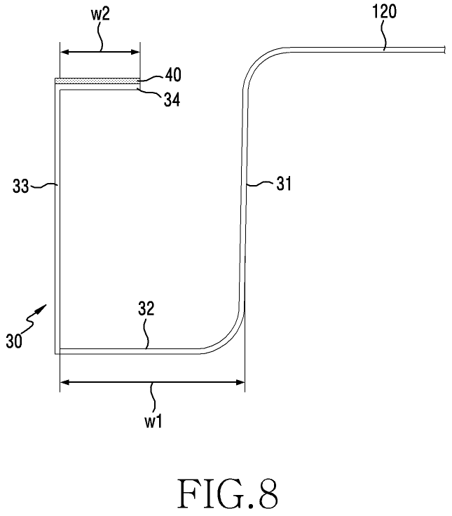

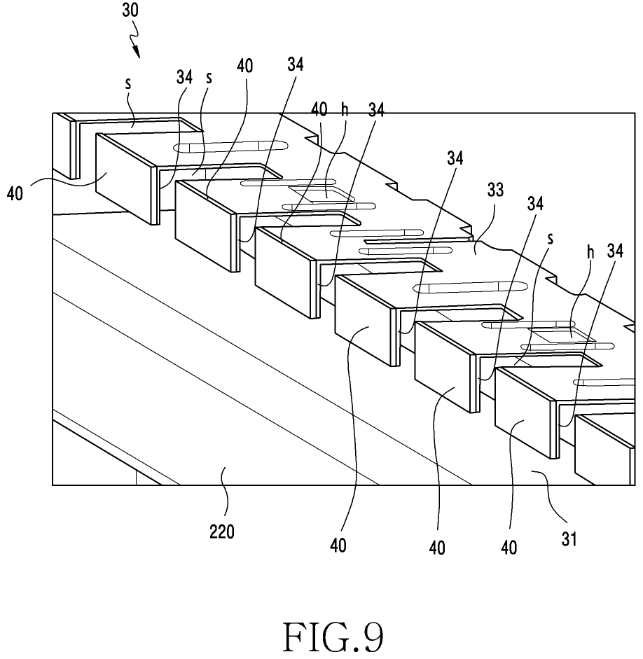

Referring to FIG. 7A to FIG. 9, according to an embodiment, a door (e.g., the door 12 of FIG. 1) may include a choke unit 30 (e.g., the choke unit 240 of FIG. 4) extending from a door frame (e.g., the door frame 220 of FIG. 3). According to an embodiment, the choke unit 30 may include first and second portions 31 and 33, an outer portion 34, and an inner portion 32. According to an embodiment, the choke unit 30 is constructed of a metal material, and may include the first side portion 31 bent at a first angle from the door frame 220. For example, the first angle may be approximately 90 degrees. According to an embodiment, the choke unit 30 may include the inner portion 32 bent at a second angle from the first side portion 31. For example, the second angle may be approximately 90 degrees. According to an embodiment, the choke unit 30 may include the second side portion 33 bent at a third angle from the inner portion 32. For example, the third angle may be approximately 90 degrees. According to an embodiment, the choke unit 30 may include the outer portion 34 bent at a fourth angle from the inner portion 32. For example, the fourth angle may be approximately 90 degrees. According to an embodiment, a free end of each of the outer portions 34 may be spaced apart from the first side portion 31.

According to an embodiment, the second side portion 33 may include a plurality of portions extending in an equidistantly split manner while extending from the inner portion 32. According to an embodiment, the portions may have at least one coupling hole h constructed to couple the choke cover 230. According to an embodiment, a slit s having a predetermined gap may be positioned between the portions.

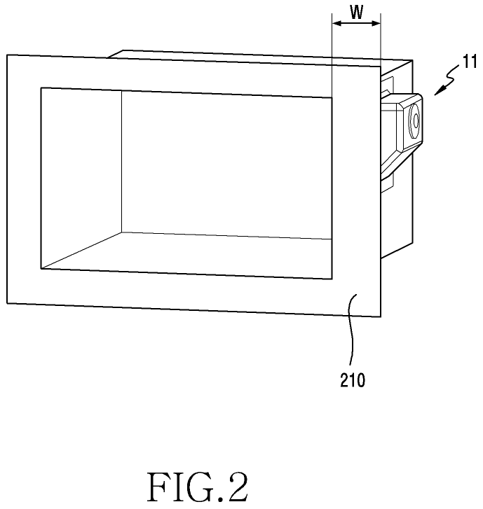

According to an embodiment, the choke unit 30 may include the outer portions 34 bent from the respective first side portions. According to an embodiment, each of the outer portions 34 may be arranged equidistantly, and may face a front panel (e.g., the front panel 210 of FIG. 2).

According to an embodiment, a microwave oven (e.g., the microwave oven 10 of FIG. 1) may include an electromagnetic shielding device. For example, the electromagnetic shielding device may be disposed between the choke unit 30 and the choke cover 230.

According to an embodiment, the choke unit 30 may have an electromagnetic shielding layer 40 disposed to each of the outer portions 34. According to an embodiment, the electromagnetic shielding layers 40 may correspond to shapes of the respective outer portions 34. For example, the electromagnetic shielding layer 40 may have a rectangular shape when viewed from above.

According to an embodiment, a portion of the choke unit 30, for example, the outer portion 34, may be disposed inside the choke cover 230. According to an embodiment, the choke cover 230 has a shape surrounding the portion of the choke unit 30, and may include a first portion facing the outer portion 34 and a front panel (e.g., the front panel 210 of FIG. 2) and a second portion coupled to the second side portion 33. According to an embodiment, the electromagnetic shielding layer 40 may be disposed between the choke cover 230 and the outer portion 34.

According to an embodiment, when the microwave oven 10 operates, electromagnetic waves generated inside the cooking chamber 111 may be totally reflected and trapped mostly inside the choke unit 30. Electromagnetic waves leaked between the front panel 210 and the choke unit 30 are absorbed by the shielding layer 40, thereby preventing the electromagnetic waves from leaking to the outside of the door 12.

According to an embodiment, since an electromagnetic shielding layer performs an electromagnetic shielding function, a size of the choke unit may be reduced in the choke unit 30. According to an embodiment, a length of the outer portion 34 may be shorter than that of the inner portion 32 or first and second side portions 31 and 33. For example, a width w2 of the outer portion 34 may be less than or equal to ½ of a width w1 of the inner portion 32. According to an embodiment, when the width w2 of the outer portion 34 is less than ½ of the width w1 of the inner portion 32, it is possible to decrease the widths of the inner and outer portions 32 and 34 of the choke unit 30 and decrease the width of the front panel, which may be advantageous for making the microwave oven 10 small in size and for increasing a volume rate of a cooking chamber.

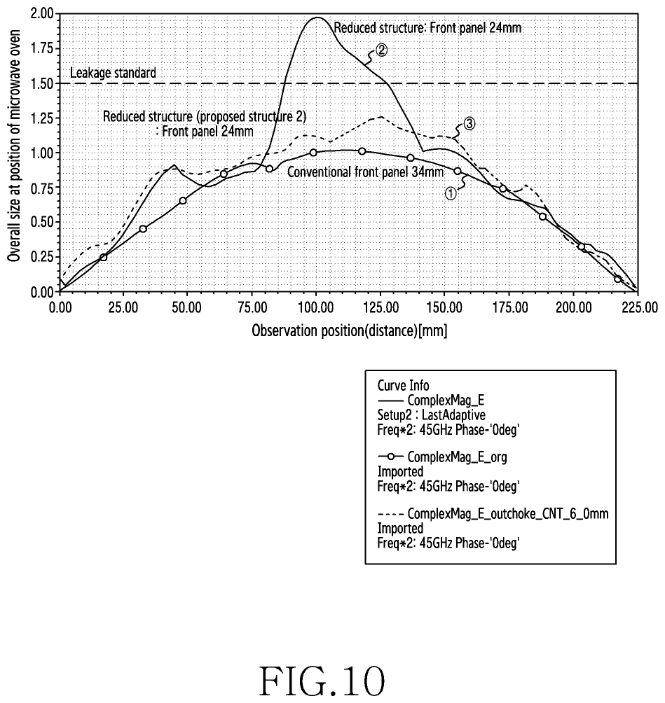

Referring to FIG. 10, a reference number 1 represents a case of a conventional electromagnetic shielding structure (the front panel 210 has a width of 34 mm), a reference number 2 represents a case of a conventional electromagnetic shielding structure in which the front panel 210 has a width of 24 mm. A reference numeral 3 represents a case of an electromagnetic shielding structure according to an embodiment of the disclosure (e.g., the electromagnetic shielding structure of FIG. 7A to FIG. 9) in which the front panel 210 has a width of 24 mm.

The conventional electromagnetic shielding structure (e.g., shown in (a) of FIG. 5A) indicated by the reference numeral 1 of FIG. 10 uses the choke cover 230 constructed of a polypropylene material having a relative permittivity of 1.5. The choke cover has a purpose of protecting the choke unit 30 and does not have an electromagnetic shielding function. The conventional electromagnetic shielding structure may not deviate from a standard of electromagnetic wave leakage.

The conventional electromagnetic shielding structure of 2 of FIG. 10 uses the choke cover 230 constructed of a polypropylene material having a relative permittivity of 1.5. The choke cover has a purpose of protecting the choke unit 30 and does not have an electromagnetic shielding function. The conventional electromagnetic shielding structure may deviate from the standard of electromagnetic wave leakage in some sections.

The electromagnetic shielding structure of 3 of FIG. 10 according to an embodiment of the disclosure may shield electromagnetic waves without deviation from the standard of electromagnetic wave leakage.

The electromagnetic shielding structure (e.g., shown in FIG. 5B) according to an embodiment may perform an electromagnetic shielding function without deviation from the standard of electromagnetic wave leakage even if the width of the front panel 210 is reduced by 10 mm compared to the conventional structure.

Various embodiments of the disclosure disclosed in the specification and the drawing are merely a specific example presented for clarity and are not intended to limit the scope of the embodiments of the disclosure. Therefore, in addition to the embodiments disclosed herein, various changes in forms and details made without departing from the technical concept of the various embodiments of the disclosure will be construed as being included in the scope of the various embodiments of the disclosure.

1. A microwave oven comprising:
a main body including a cooking chamber and a front panel;
a door to the main body including a door frame corresponding to the front panel; and
a shielding device connected to the door to shield electromagnetic waves leaking from the cooking chamber,
wherein the shielding device comprises:
a choke unit extending from the door frame and including a plurality of portions constructed by being bent at least once; and
a choke cover covering the choke unit, wherein the choke cover comprises:
a first portion constructed of a first material coupled to a portion of the choke unit; and
a second portion connected integrally with the first portion and constructed of a second material different from the first material.

2. The microwave oven of claim 1, wherein the choke unit comprises:
a first side portion bent at a first angle from the door frame;
an inner portion bent at a second angle from the first side portion;
a second side portion bent at a third angle from the inner portion and parallel to the first side portion, wherein the second side portion has at least one coupling hole; and
an outer portion bent at a fourth angle from the second side portion.

3. The microwave oven of claim 2, wherein the first portion is coupled to the second side portion and the outer portion, and wherein the second portion extends from an end of the first portion towards the first side portion.

4. The microwave oven of claim 2, wherein a width of the outer portion is less than or equal to half of a width of the inner portion.

5. The microwave oven of claim 1, wherein the first material includes a high permittivity shielding material, and the high permittivity shielding material includes one of a Carbon Nano Tube (CNT) material or a Chlorinated Polyethylene (CPE) material.

6. The microwave oven of claim 2, wherein an end of the second side portion is constructed to face the inner portion.

7. The microwave oven of claim 1, wherein the second material includes a polypropylene material.

8. A microwave oven comprising:
a main body including a cooking chamber and a front panel;
a door to the main body including a door frame corresponding to the front panel; and
a shielding device connected to the door to shield electromagnetic waves leaking from the cooking chamber,
wherein the shielding device comprises:
a choke unit extending from the door frame and including a plurality of portions constructed by being bent at least once;
a choke cover covering the choke unit and coupled to a portion of the choke unit; and
an electromagnetic shielding layer between the choke unit and the choke cover.

9. A microwave oven of claim 8, wherein the choke unit comprises:
a first side portion bent at a first angle from the door frame;
an inner portion bent at a second angle from the first side portion;
a second side portion bent at a third angle from the inner portion and parallel to the first side portion, wherein the second side portion has at least one coupling hole; and
an outer portion bent at a fourth angle from the second side portion and including a plurality of arranged outer potions.

10. A microwave oven of claim 9, wherein the choke cover is coupled to the second side portion, and wherein the choke cover comprises:
a first portion connected to the second side portion; and
a second portion connected to the outer portion and facing the front panel.

11. The microwave oven of claim 10, wherein the electromagnetic shielding layer is a layer between the second portion and the outer portion.

12. The microwave oven of claim 9, wherein the electromagnetic shielding layer corresponds to a shape of the outer portion.

13. The microwave oven of claim 12, wherein the electromagnetic shielding layer is arranged equidistantly from the second portion and the outer portion.

14. The microwave oven of claim 9, wherein the electromagnetic shielding layer is in contact with the choke cover and the outer portion.

15. The microwave oven of claim 9, wherein a width of the outer portion is less than or equal to half of a width of the inner portion.
